(19) United States
(12) Patent Application Publication
(10) Pub. No.: US 2016/0013300 A1
(43) Pub. Date: Jan. 14, 2016

(54) SEMICONDUCTOR DEVICE, DRIVE DEVICE FOR SEMICONDUCTOR CIRCUIT, AND POWER CONVERSION DEVICE

(71) Applicant: HITACHI, LTD., Chiyoda-ku, Tokyo (JP)

(72) Inventors: Takayuki HASHIMOTO, Tokyo (JP); Mutsuhiro MORI, Tokyo (JP)

(21) Appl. No.: 14/770,448

(22) PCT Filed: Feb. 25, 2013
(86) PCT No.: PCT/JP2013/054657

§ 371 Date: Aug. 25, 2015

(51) Int. Cl. H01L 29/739; H01L 29/36; H02M 7/537; H01L 29/423

(52) U.S. Cl. CPC H01L 29/7391; H01L 29/4236; H01L 29/36; H01L 29/7393; H02M 7/537

(57) ABSTRACT

A semiconductor device according to the present invention includes: a first semiconductor layer of a first conductivity type; a second semiconductor layer of the first conductivity type adjacent to the first semiconductor layer and having an impurity concentration lower than the first semiconductor layer; a third semiconductor layer of a second conductivity type adjacent to the second semiconductor layer; a fourth semiconductor layer of the first conductivity type located within the third semiconductor layer; a first electrode coupled to the third semiconductor layer and the fourth semiconductor layer; a second electrode coupled to the first semiconductor layer; and an insulated gate provided over the respective surfaces of the third semiconductor layer and the fourth semiconductor layer, wherein peak value of the impurity concentration of the third semiconductor layer is in the range of 2×10¹⁶ cm⁻³ or more and 5×10¹⁸ cm⁻³ or less.

### TECHNICAL FIELD

The present invention relates to a semiconductor device, a drive device for a semiconductor circuit using the semiconductor device, and a power conversion device. More particularly, the present invention relates to a semiconductor device suitable for wide range of applications from small power devices such as air conditioners and microwaves, to large power devices such as inverters for railroad and steel plants, and relates to a drive device for a semiconductor circuit using the same as well as a power conversion device.

### BACKGROUND ART

Many inverters and converters are used in recent power saving and new energy power conversion devices, and it is necessary to promote the use of such power conversion devices in order to achieve low carbon society. FIG. 18 shows an example of an inverter capable of achieving energy savings by variably controlling the speed of a motor 950. An electric energy from a power supply 960 is changed to AC of a desired frequency by using an IGBT (Insulated Gate Bipolar Transistor) 700, which is a kind of power semiconductor, to variably control the speed of rotation of the motor 950. The motor 950 is a three-phase motor with inputs of U-phase 910, V-phase 911, and W-phase 912. The input power of the U-phase 910 is supplied by turning on a gate circuit 800 of the IGBT 700 (hereinafter referred to as the upper arm IGBT) in which a collector is coupled to a power supply terminal 900 on the plus side. The input power of the U-phase 910 can be stopped by turning off the gate circuit 800. By repeating this operation, the power of desired frequency can be supplied to the motor 950.

A flywheel diode 600 is connected in reverse parallel to the IGBT 700. For example, when the upper arm IGBT 700 is turned off, the flywheel diode 600 releases the energy accumulated in the coil of the motor 950 by turning the current flowing through the IGBT 700 to the flywheel diode 600 that is connected in reverse parallel to the IGBT 700 (hereinafter referred to as the lower arm IGBT) in which an emitter is coupled to a power supply terminal 901 on the minus side. When the upper arm IGBT 700 is turned on again, the lower arm flywheel diode 600 is brought into a nonconductive state, so that the power is supplied to the motor 950 through the upper arm IGBT 700. The IGBT 700 and the flywheel diode 600 generate conduction losses during conduction and generate switching during switching. For this reason, it is necessary to reduce the conduction losses of the IGBT 700 and the flywheel diode 600 as well as their switching losses in order to reduce the size and increase the efficiency of the inverter.

The technology described in Patent Literature 1 is known as a technology for reducing the conduction loss and recovery loss of the flywheel diode 600. This technology can reduce the sum of the switching loss and the conduction loss, namely, the total loss, by controlling the accumulated charge in the diode to control the ratio of the switching loss and the conduction loss, even when the period of ON state and the period of OFF state change from moment to moment.

### CITATION LIST

### Patent Literature

Patent Literature 1: Japanese Patent Application Laid-Open No. HEI 6 (1994)-97468 (FIG. 16)

### SUMMARY OF INVENTION

### Technical Problem

However, the present inventors have found that the conventional technology described above has the following problem. In a trench gate diode disclosed in Patent Literature 1 (FIG. 16 of Patent Literature 1), both the loss (the sum of the conduction loss and the recovery loss) and the breakdown voltage are determined by the impurity concentration and depth of a p layer (reference numeral 4 in FIG. 16). Thus, there is a problem that it is difficult to optimize the loss and the breakdown voltage independently.

In order to minimize the loss (the sum of the conduction loss and the recovery loss), it is necessary to set the impurity concentration of the p layer (reference numeral 4 in FIG. 16) within a predetermined range. If the impurity concentration of the p layer is high, it is difficult to reduce the potential with respect to the electrons of a channel inversion layer, namely, an n type inversion layer formed in a p type layer adjacent to a gate insulating film, so that the amount of hole injection may not be reduced. As a result, the recovery loss is increased. On the other hand, if the impurity concentration of the p layer is low, the amount of hole injection is small during conduction. As a result, the conduction loss is increased.

With respect to the breakdown voltage, the impurity concentration of the p layer should be increased to a certain value or more. This is because if the concentration of the p layer is low, the depletion layer spreading over the p layer reaches the channel inversion layer (n type) when a reverse voltage is applied between the anode and cathode of the diode, and as a result, the breakdown voltage is reduced.

In other words, from the point of view of the loss, it is necessary to set the impurity concentration of the p layer within a desired range, while from the point of view of the breakdown voltage, it is necessary to set the impurity concentration of the p layer to a certain value or more. There is no problem if the two impurity concentration ranges overlap. However, when there is no overlapping range, it is necessary to sacrifice either of the two impurity concentration ranges.

According to the studies of the present inventors, it is found that the optimal value of the p layer impurity concentration determined from the loss is different from the optimal value of the p layer impurity concentration determined from the breakdown voltage. The breakdown voltage is an uncompromising specification and should not be reduced. For this reason, eventually only the loss can be reduced in a range in which the breakdown voltage is not reduced, so that it is difficult to achieve a sufficient reduction in the loss.

The present invention has been made in view of the above problem, and an object of the present invention is to reduce both the conduction loss and the recovery loss without reducing the breakdown voltage of the diode.

### Solution to Problem

In order to solve the above problem, the role of the p layer is limited to the reduction in the loss, and the problem with the breakdown voltage is solved by another method. In other words, a semiconductor device according to the present invention includes: a first semiconductor layer of a first conductivity type; a second semiconductor layer of the first conductivity type, which is adjacent to the first semiconductor layer and has an impurity concentration lower than the first semiconductor layer; a third semiconductor layer of a second conductivity type adjacent to the second semiconductor layer; a fourth semiconductor layer of the first conductivity type located within the third semiconductor layer; a first electrode electrically coupled to the third semiconductor layer and the fourth semiconductor layer; a second electrode electrically coupled to the first semiconductor layer; and an insulated gate provide over each of the surfaces of the third semiconductor and the fourth semiconductor layer. Then, the peak value of the impurity concentration of the third semiconductor layer is in the range of 2×10¹⁶ cm⁻³ or more and 5×10¹⁸ cm⁻³ or less.

Here, the first semiconductor layer, the second semiconductor layer, the third semiconductor layer, the fourth semiconductor layer, the first electrode, and the second electrode correspond to, for example, an n+ type cathode layer, an n− type drift layer, a p type channel layer, an n+ anode layer, an anode electrode, and a cathode electrode, respectively, which will be described in the following embodiments.

### Advantageous Effects of Invention

According to the present invention, it is possible to provide a diode with low loss and low noise, so that it is possible to increase the efficiency of a semiconductor device and a power conversion device, and to reduce their size or cost.

### BRIEF DESCRIPTION OF DRAWINGS

FIG. 1 is a cross-sectional view of a semiconductor device which is a first embodiment of the present invention.

FIG. 2 shows a hole density distribution between anode and cathode.

FIG. 3 shows the output characteristics.

FIG. 4 shows the relationship between the forward voltage drop and the impurity concentration of the p type channel layer.

FIG. 5 shows potentials when the gate insulating film is thin and when it is thick.

FIG. 6 shows a waveform of the forward voltage.

FIG. 7 shows a gate drive sequence during recovery.

FIG. 8 shows the relationship between the forward voltage drop and the recovery loss.

FIG. 9 shows recovery waveforms.

FIG. 10 is a cross-sectional view of a semiconductor device which is a second embodiment of the present invention.

FIG. 11 shows the relationship between the sheet carrier of the p− type breakdown voltage holding layer and the forward voltage drop.

FIG. 12 shows the relationship between the depth of the p− type breakdown voltage holding layer and the impurity concentration.

FIG. 13 shows an electric field distribution.

FIG. 14 shows a gate drive sequence during recovery.

FIG. 15 is a cross-sectional view of a semiconductor device which is a third embodiment of the present invention.

FIG. 16 is a cross-sectional view of a semiconductor device which is a fourth embodiment of the present invention.

FIG. 17 is a cross-sectional view of a semiconductor device which is a fifth embodiment of the present invention.

FIG. 18 is a circuit block diagram for illustrating the conventional power conversion device, as well as a power conversion device according to a ninth embodiment.

FIG. 19 is a circuit diagram of a drive device which is a sixth embodiment of the present invention.

FIG. 20 is a circuit diagram of a drive device which is a seventh embodiment of the present invention.

FIG. 21 is a drive device which is an eighth embodiment of the present invention.

### DESCRIPTION OF EMBODIMENTS

Hereinafter, the embodiments of the present invention will be described with reference to the accompanying drawings. Note that the symbols of n−, n, and n+ in the figures show that the semiconductor layers are n type, showing that the impurity concentration is relatively high in this order. Further, the symbols of p−, p and p+ show that the semiconductor layers are p type, showing that the impurity concentration is relatively high in this order.

### First Embodiment

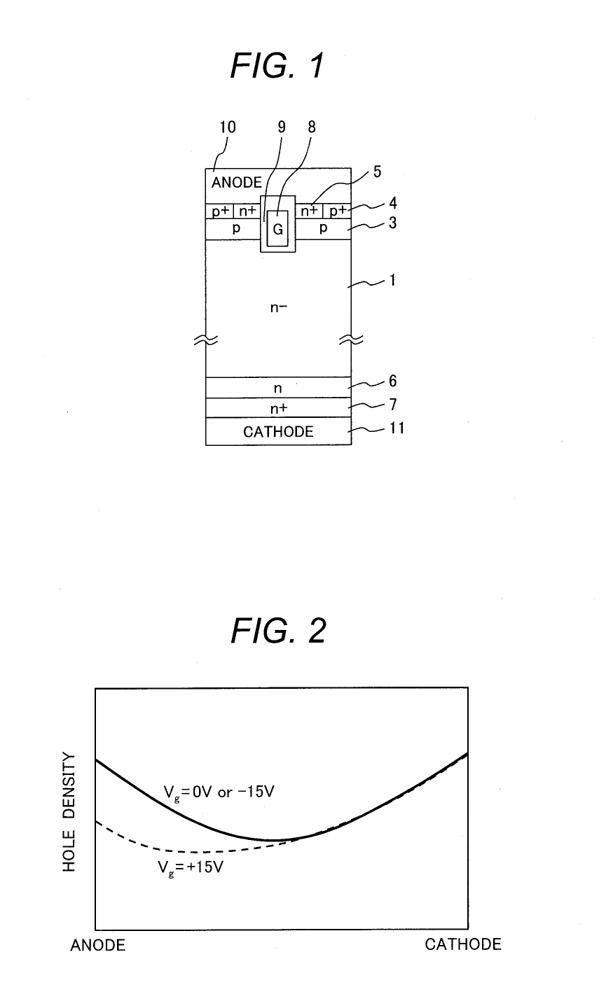

FIG. 1 is a cross-sectional view of an insulated gate type vertical semiconductor device which is a first embodiment of the present invention. The present embodiment is a trench gate control diode including: an n− type drift layer 1; a p type channel layer 3 vertically adjacent to the n− type drift layer; a p+ type anode layer 4 and an n+ anode layer 5 that are provided within the p type channel layer 3 and are adjacent to each other in the lateral direction; an n type buffer layer 6 vertically adjacent to the n− type drift layer 1 on the opposite side of the p type channel layer 3; and an n+ type cathode layer 7 vertically adjacent to the n type buffer layer 6 on the opposite side of the n− type drift layer 1. Further, the present embodiment also includes an insulated gate, which is a trench gate type, having a gate electrode 8 provided over each of the surfaces of the n− type drift layer 1, the p type channel layer 3, and n+ type anode layer 5, through a gate insulating film 9 in a so-called trench groove. Further, the anode electrode 10 is electrically coupled to the n+ anode layer 5 by an ohmic contact. Further, the anode electrode 10 is brought into ohmic contact with the p+ type anode layer 4, and thus is electrically coupled to the p+ type anode layer 4 and the p type channel layer 3. The cathode electrode 11 is brought into ohmic contact with the n+ cathode layer 7, and thus is electrically coupled to the n+ type cathode layer 7, the n type buffer layer 6, and the n− type drift layer 1.

In the present embodiment, the gate electrode 8 is set to the same potential as the anode electrode 10 or to a negative voltage with respect to the anode electrode 10. In this way, a large part of the anode current flows through a first current path passing through the p+ type anode layer 4 and the p type channel layer 3. Because the p type channel layer 3 is included in the first current path, a large number of holes are injected into the n− type drift layer 1 from the p type channel layer 3, so that the forward voltage drop (Vf) is reduced. As a result, the conduction loss is reduced. On the other hand, during recovery, the gate electrode 8 is set to a positive voltage with respect to the anode electrode 10. In this way, the current also flows through a second current path passing through the n type inversion layer, which is formed at the interface between the gate insulating film 9 and the p type channel layer 3, and through the n+ type anode layer. The p type channel layer 3 is not included in the second current path, so that the hole injection to the n− type drift layer 1 is reduced. As a result, the recovery loss is reduced. In this way, the loss is controlled by the presence or absence of the inversion layer formed in the p type channel layer 3. On the other hand, as for the breakdown voltage, the lower end of the p type channel layer 3 is located above the lower end of the gate electrode 8, so that the influence of the p type channel layer 3 on the breakdown voltage is small. Thus, the impurity concentration and depth of the p type channel layer 3 can be set so that the loss can be reduced without affecting the breakdown voltage.

FIG. 2 shows a hole density distribution between the anode and the cathode during conduction. When the positive voltage (Vg=+15 V in the figure) is applied to the gate, the hole density on the anode side is reduced. This is because the n type inversion layer is formed at the interface between the p type channel layer 3 and the gate insulating film 9, and the electrons injected from the n+ type cathode layer 7 flow to the anode electrode 10 through the n type inversion layer, so that the hole injection from the p type channel layer 3 is reduced. When the gate electrode is 0 volt or the negative voltage (Vg=0 V or −15 V in the figure), the current path through the n type inversion layer disappears, so that the hole density on the anode side is increased.

Note that in the present embodiment, the n type inversion layer is formed in the p type channel layer 3 by setting the gate voltage to the threshold value or more. However, the potential of the channel with respect to the electrons is reduced even when the gate voltage is set to a positive voltage lower than the threshold value. As a result, the electrons flow to the anode electrode through the path in which the potential is reduced. Thus, in this case also, the hole density is reduced on the anode side during conduction.

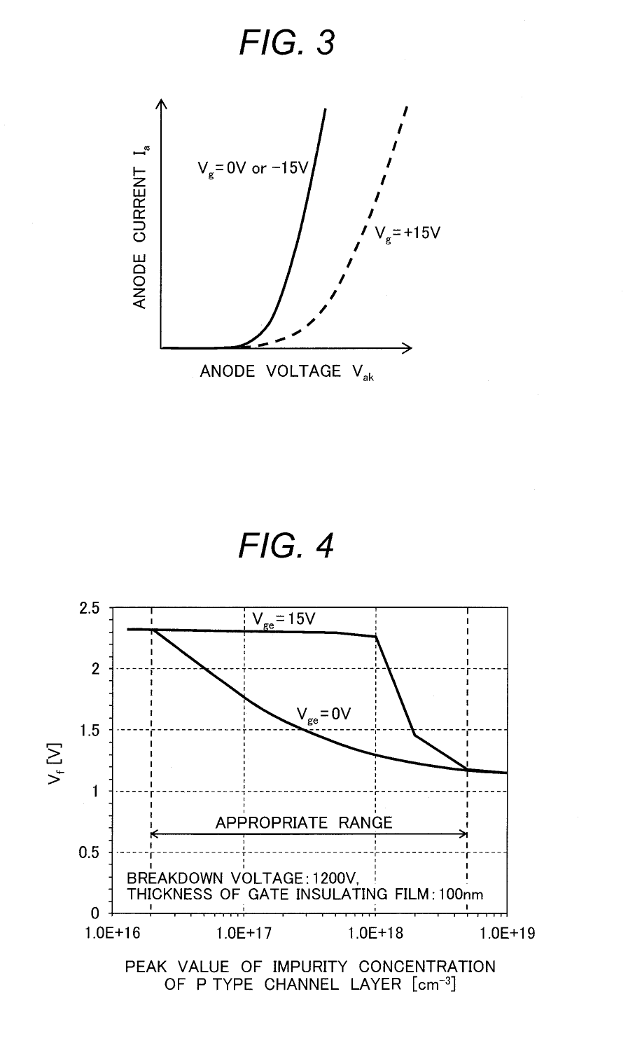

FIG. 3 shows the output characteristics when positive voltage is applied to the gate electrode 8, and when 0 volt (or negative voltage) is applied to the gate electrode 8. When 0 volt (or negative voltage) is applied to the gate electrode 8, the anode current is large and the forward voltage Vf is small because the hole density on the anode side is high. On the other hand, when the positive voltage is applied to the gate electrode 8, the anode current is small and the forward voltage Vf is large because the hole density on the anode side is low. In other words, in the present embodiment, it is possible to practically switch between the diode whose forward voltage drop (Vf) is small, namely, the diode with large recovery loss, and the diode whose forward voltage drop (Vf) is large, namely, the diode with small recovery loss, by the gate electrode 8. In this way, both the conduction loss and the recovery loss, or the switching loss can be reduced.

Next, a description will be made of the peak value of the impurity concentration in the vicinity of the interface of the gate insulating film 9 of the p type channel layer 3, according to the present embodiment. Note that the impurity concentration in the vicinity of the interface of the gate insulating film 9 is the impurity concentration in the region affecting the threshold voltage, which is practically the peak value of the impurity concentration in the vertical direction of the p type channel layer 3 as long as the impurity concentration distribution in the lateral direction of the p type channel layer 3 is flat.

FIG. 4 is shows the relationship between the forward voltage drop Vf (vertical axis) and the peak value of the impurity concentration of the p type channel layer 3 (horizontal axis). The point at which Vge=0 V corresponds to the forward voltage drop (Vf) during conduction. The point at which Vge=15 V corresponds to the forward voltage drop (Vf) during recovery. The smaller Vf of Vge=0 V, the better for reducing the conduction loss, while the greater Vf of Vge=15 V, the better for reducing the recovery loss. Thus, the greater the difference between Vge=0 V and Vge=15 V is, the more the sum of the conduction loss and the switching loss can be reduced. When Vf of Vge=0 V and Vf of Vge=15 V are equal to each other, it is shown that the gate electrode 8 is practically ineffective. From this point of view, the appropriate range of the impurity concentration of the p type channel layer 3 in FIG. 4 is 2×10¹⁶ cm⁻³ or more and 5×10¹⁸ cm⁻³ or less. When the impurity concentration is 1×10¹⁸ cm⁻³ in this range, the difference between Vge=0 V and Vge=15 V is maximum. Then, the sum of the conduction loss and the switching loss is minimized.

Next, a description will be made of the consistency of the value of the impurity concentration of the p type channel layer 3 shown in FIG. 4. Here, the consistency means that the numerical range of FIG. 4 is valid when the device parameters (gate voltage, gate insulating film thickness, gate electrode depth, p layer depth, and breakdown voltage) are changed.

With respect to the depth of the gate electrode and the depth of the p type channel layer, when the gate electrode 8 is deeper than the p type channel layer 3, it is obvious that the appropriate range of the impurity concentration of the p type channel layer 3 of FIG. 4 is constant, without depending on the depth of the gate electrode and on the depth of the p type channel layer. Note that the appropriate range of the impurity concentration of the p type channel layer 3 is constant also for the breakdown voltage.

When increasing the gate voltage, it is necessary to increase the thickness of the gate insulating film from the point of view of the breakdown voltage of the gate insulating film. On the other hand, when reducing the gate voltage, it is possible to reduce the thickness of the gate insulating film from the point of view of the breakdown voltage of the gate insulating film. In other words, the gate voltage and the gate insulating film thickness are the parameters that are changed in conjunction with each other. With respect to the gate voltage and the gate insulating film thickness, it is necessary to take into account the following cases: when the gate voltage is high and the gate insulating film is thick, and when the gate voltage is low and the gate insulating film is thin.

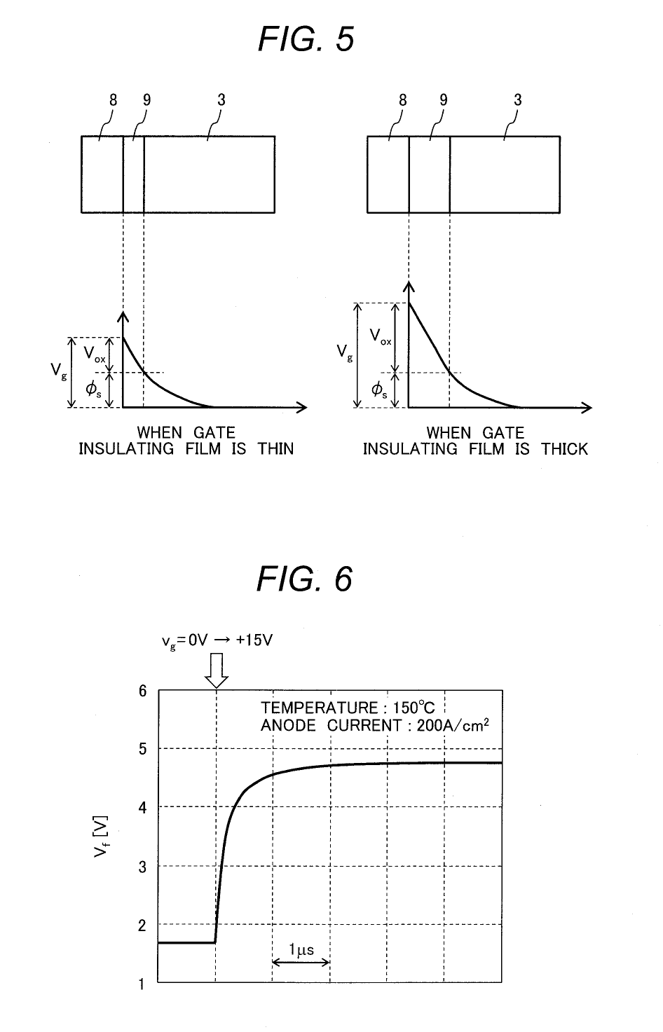

FIG. 5 shows the potentials when the gate insulating film is thin and when the gate insulating film is thick. Reference symbol Vg represents the gate voltage, Vox represents the voltage applied to the gate insulating film, and φs represents the potential at the interface of the gate insulating film 9 of the p type channel layer 3. The voltage applied to the gate insulating film is different due to the difference in the gate insulating film thickness, but the potential φs of the p type channel layer 3 is substantially the same. This is because the potential φs of the p type channel layer 3 is constant without depending on the thickness of the gate insulating film, showing that there is a consistency in the appropriate range of the impurity concentration of the p type channel layer 3 shown in FIG. 4.

As described above, there is a consistency in the appropriate range of the impurity concentration of the p type channel layer 3 shown in FIG. 4 when the various device parameters (gate voltage, gate insulating film thickness, gate electrode depth, p layer depth, and breakdown voltage) are changed.

Next, the gate drive sequence of the present embodiment will be described.

FIG. 6 shows the waveform of the forward voltage drop (Vf) before and after switching the gate voltage Vg from 0 V to +15 V. The time when Vf changes from a low state to a high state is about 2 μs. This is because it takes time until the gate voltage Vg is reflected in the total amount of holes in the n− type drift layer 1 after switching the gate voltage Vg to +15 V. Note that FIG. 6 shows the state under the condition that the breakdown voltage is 1200 V, so that the transition time until Vf is stable increases when the breakdown voltage is higher than 1200 V (when the n− type drift layer 1 is thick). However, the holes move by diffusion and drift to and through the n− type drift layer 1, so that the transition time is in the order of several μs.

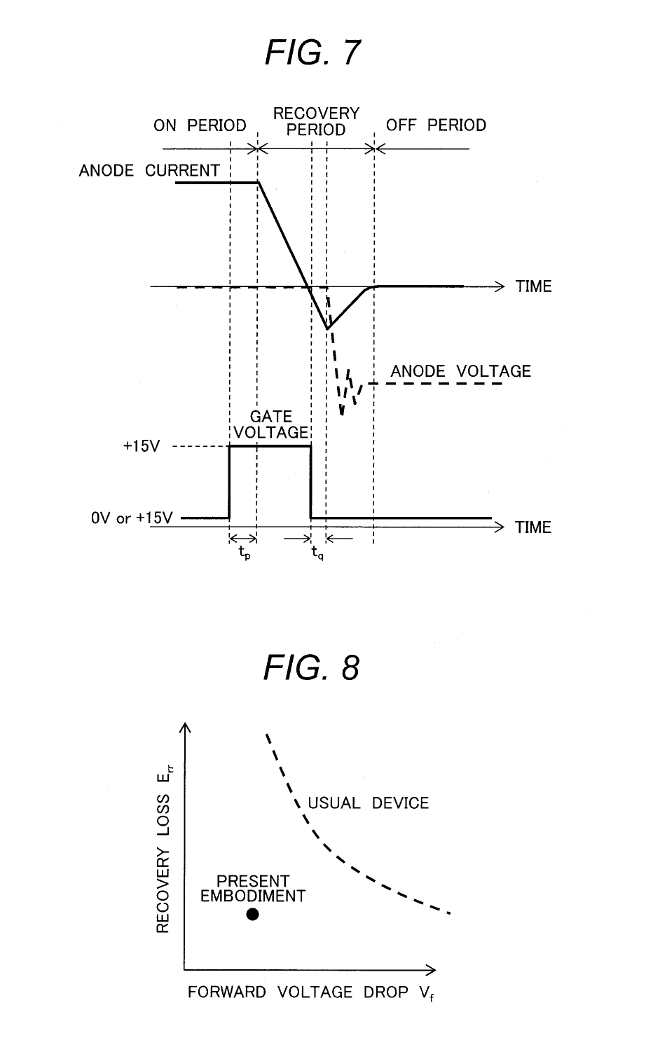

FIG. 7 shows the date drive sequence during recovery according to the present embodiment. The upper part shows the waveforms of the anode current and the anode voltage during recovery of the diode according to the present embodiment. The lower part shows the waveform of the gate voltage. The positive voltage is applied to the gate electrode just before the anode current is reduced. In this way, the hole density is reduced, and thus the recovery loss is reduced. When the positive voltage is applied to the gate electrode, the forward voltage drop (Vf) is increased, so that the conduction loss is increased. However, the increase in the conduction loss is at a level that can be ignored from the point of view of the whole loss (the conduction loss + the recovery loss) by increasing the gate voltage just before recovery. The difference tp between the time point when the anode current starts to drop and the time point when the gate voltage is increased is preferably 2 μs or more. This is because if tp is too short, the hole density is not sufficiently reduced, so that the recovery loss is increased.

In the present embodiment, the gate voltage is returned to 0 V before the negative voltage is applied to the anode. The difference tq between the time point when the gate voltage is set to 0 V and the time point when the negative voltage starts to be applied to the anode, is positive. The reason why the gate voltage is returned to 0 V is that when the gate voltage is +15 V, the anode and the cathode are short circuited through the n type inversion layer and thus the breakdown voltage is reduced.

FIG. 8 shows the relationship between the forward voltage drop (Vf) and the recovery loss (Err) according to the present embodiment. The dashed line corresponds to a usual pin diode. In the present embodiment, it is possible to reduce both the forward voltage (Vf) and the recovery loss (Err) by dynamically controlling the gate voltage within one cycle of switching. As a result, the trade-off characteristics can be improved.

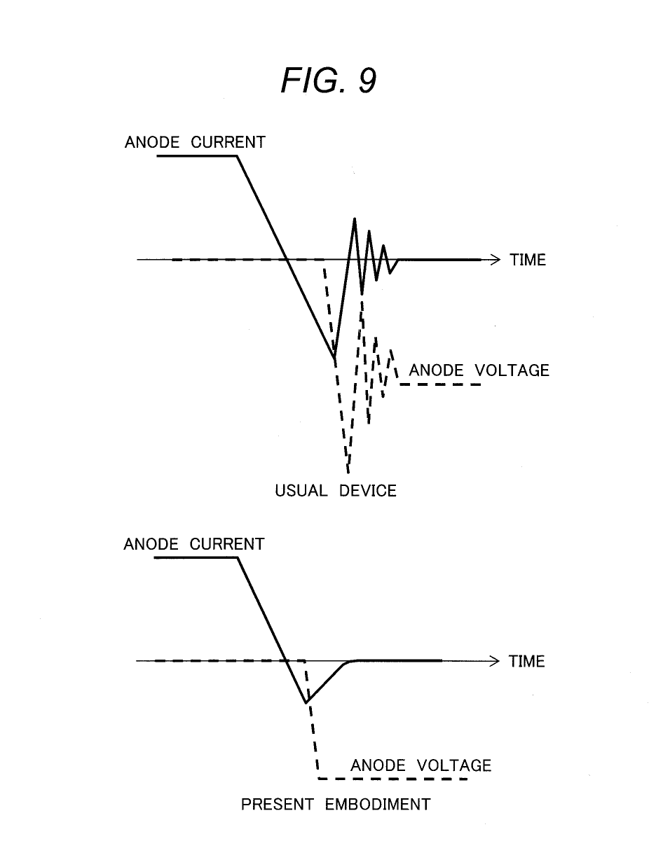

FIG. 9 shows the waveforms of the anode current and the anode voltage during recovery according to the present embodiment. The upper part shows the usual pin diode and the lower part shows the present embodiment. The forward voltage drop (Vf) is the same in the usual pin diode and in the present embodiment. In the usual pin diode, the peak value of the reverse anode current (reverse recovery current lrp) is large, so that the peak value of the anode voltage (surge voltage) is large and vibration appears both in the anode current and in the anode voltage. In contrast, in the present embodiment, the peak value of the reverse anode current is small, so that the peak value of the anode voltage is small and nearly no vibration occurs. In the present embodiment, the reason why the peak value of the reverse anode current is small is that the hole density on the anode side is reduced due to the application of the positive voltage to the gate electrode. During recovery, the peak values of the anode current and the anode voltage are reduced, so that the noise is reduced. For this reason, it is possible to prevent malfunctions of the power conversion device using the semiconductor device of the present embodiment, as well as the electronic equipment. Further, it is not required to have any noise shielding parts, so that it is possible to reduce the size of the power conversion device and the electronic equipment.

Note that it is well known that in the insulated gate type power device, the electrical properties are degraded as the number of times of switching increases. The cause of the degradation of the electrical properties is due to charge (hole) injected into the gate insulating film from the p type body layer during switching. In contrast, in the present embodiment, the charge (hole) is reduced during switching, so that it is possible to prevent such a degradation.

As described above, according to the present embodiment, it is possible to reduce both power loss and noise, so that it is possible to increase the efficiency and reduce the size of the semiconductor device and the power conversion device using the same. Further, in the present embodiment, the degradation of the electrical properties is prevented, so that the reliability of the semiconductor device and the power conversion device using the same is increased.

### Second Embodiment

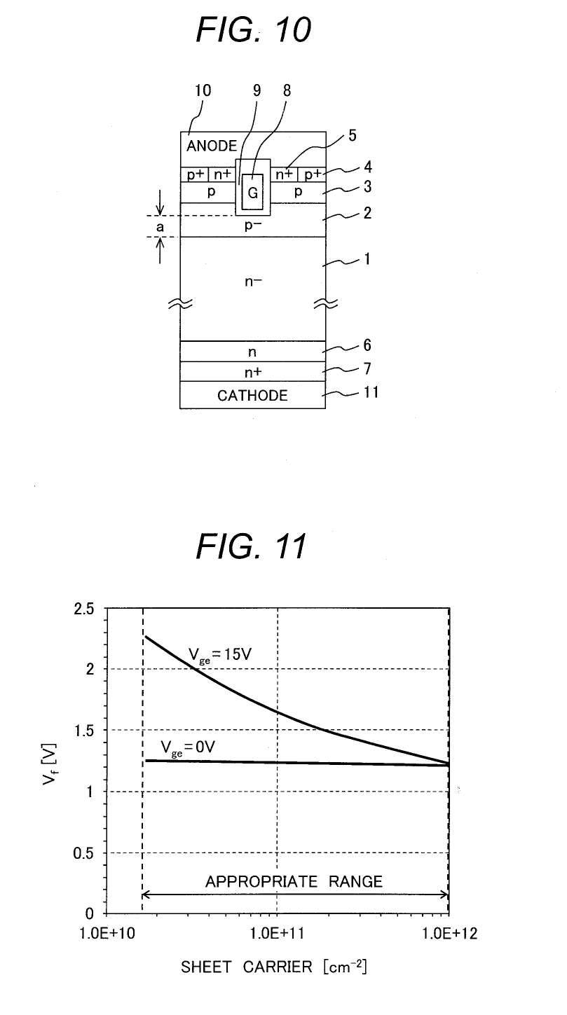

FIG. 10 is a cross-sectional view of an insulated gate type vertical semiconductor device which is a second embodiment of the present invention. Similarly to the first embodiment, the present embodiment is a trench gate control diode. The present embodiment is different from the first embodiment in that a p− type breakdown voltage holding layer 2 is provided between the n− type drift layer 1 and the p type channel layer 3, in such a way that the p− type breakdown voltage holding layer 2 is vertically adjacent to the both layers.

FIG. 11 shows the relationship between the sheet carrier of the p− type breakdown voltage holding layer 2 and the forward voltage drop (Vf), according to the present embodiment. Here, the sheet carrier is the numerical value obtained by integrating the impurity concentration from the lower end of the gate insulating film 9 to the lower end of the p− type breakdown voltage holding layer 2 (corresponding to “a” in FIG. 10) in the depth direction. In order to maintain the breakdown voltage with the positive voltage applied to the gate electrode 8, it is necessary to prevent the depletion layer, which extends from the pn junction between the p− type breakdown voltage holding layer 2 and the n− type drift layer 1 to the inside of the p− type breakdown voltage holding layer 2, from reaching the gate insulating film 9. For this reason, the lower limit of the sheet carrier of the p− type breakdown voltage holding layer 2 is preferably 1.5×10¹⁰ cm⁻². On the other hand, the upper limit of the sheet carrier is 1×10¹² cm⁻² with the condition that Vf of the gate voltage Vg=+15 V matches Vf of Vg=0 V. In other words, the appropriate range of the sheet carrier of the p− type breakdown voltage holding layer 2 is 1.5×10¹⁰ cm⁻² or more and 1×10¹² cm⁻² or less.

When the sheet carrier of the p− type breakdown voltage holding layer 2 is 1.5×10¹⁰ cm⁻² in the appropriate range described above, the difference in Vf between Vge=0 V and Vge=15 V is maximum. At this time, the sum of the conduction loss and the switching loss is minimized. Further, from the point of view of the breakdown voltage, the sheet carrier of the p− type breakdown voltage holding layer 2 is 1.5×10¹⁰ cm⁻² or more. Thus, in the present embodiment, in order to reduce the power loss while maintaining the breakdown voltage, the sheet carrier is preferably set to 1.5×10¹⁰ cm⁻². Here, Vf of the gate voltage Vge, which is 0 V, is constant without depending on the sheet carrier, because the amount of the hole injection is determined by the impurity concentration of the p type channel layer 3 and is unlikely to be affected by the p− type breakdown voltage holding layer 2.

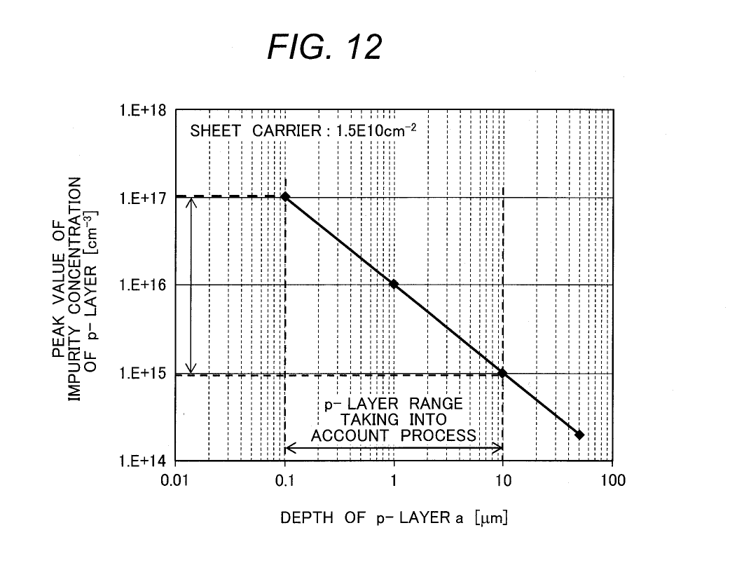

FIG. 12 shows the relationship between the depth a of the p− type breakdown voltage holding layer 2 and the peak value of the impurity concentration when the sheet carrier of the p− type breakdown voltage holding layer 2 is 1.5×10¹⁰ cm⁻². Note that the impurity distribution of the p− type breakdown voltage holding layer 2 is a box profile. When the sheet carrier is constant, namely, when the product of the depth a and the impurity concentration is constant, the impurity concentration is small as long as the depth a of the p− type breakdown voltage holding layer 2 is large. The impurity concentration is large as long as the depth a of the p− type breakdown voltage holding layer 2 is small.

In view of the fluctuations of the depth of the p− type breakdown voltage holding layer 2 and the impurity concentration in the production process (ion implantation or the like), the lower limit of the depth of the p− type breakdown voltage holding layer 2 is about 0.1 μm. On the other hand, the upper limit of the depth of the p− type breakdown voltage holding layer 2 is about 10 μm. This is because the diffusion layer, which is the deepest layer in the production process, is a p type layer (about 10 μm deep) in the vicinity of the chip that maintains the breakdown voltage. Thus, a diffusion process is performed at a high temperature for a long time to form a diffusion layer of 10 μm or more.

As described above, the depth a of the p− type breakdown voltage holding layer 2 is 0.1 μm or more and 10 μm or less. The corresponding range of the peak value of the impurity concentration of the p− type breakdown voltage holding layer 2 is 1.5×10¹⁵ cm⁻³ or more and 1.5×10¹⁷ cm⁻³ or less. Given the production variations in this concentration range, it is desirable that the depth of the p− type breakdown voltage holding layer 2 is set to about 1 μm and the peak value of the impurity concentration of the p− type breakdown voltage holding layer 2 is set to about 1×10¹⁶ cm⁻³.

As described in the description of FIG. 4, given the fact that the appropriate value of the impurity concentration of the p− type breakdown voltage holding layer 2 is about 1×10¹⁸ cm⁻³, the difference in the impurity concentration between the p− type breakdown voltage holding layer 2 and the p type channel layer 3 is as large as about double digits.

Next, a description will be made of the consistency of the value range of the sheet carrier and impurity concentration of the p− type breakdown voltage holding layer 2 described in FIGS. 11 and 12, namely, the fact that the value range of the sheet carrier and impurity concentration of the p− type breakdown voltage holding layer 2 is constant with respect to different breakdown voltages.

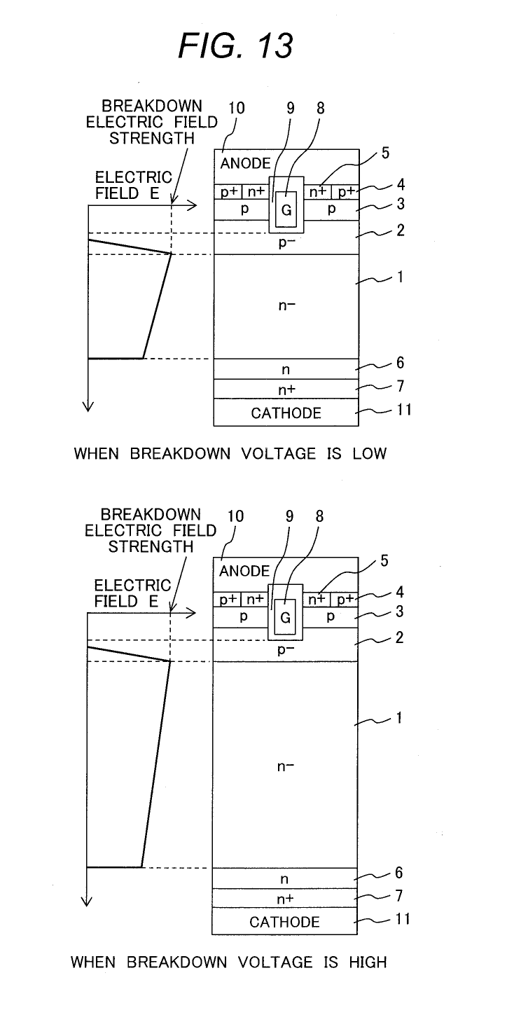

FIG. 13 shows the electric field distributions in the depth direction for the two cases. One is when the breakdown voltage is low, namely, when the n− type drift layer 1 is thin and the impurity concentration is high. The other is when the breakdown voltage is high, namely, when the n− type drift layer 1 is thick and the impurity concentration is low. The electric field distribution of the n− type drift layer 1 changes due to the variation of the breakdown voltage, however, the electric field distribution of the p− type breakdown voltage holding layer 2 is constant.

Here, the breakdown electric field strength in the electric field distribution is the critical value of the electric field when the semiconductor device may not block the voltage (break down), which is the physical property value determined by the semiconductor material. The breakdown voltage is the voltage at which the electric field strength in the junction part between the p− type breakdown voltage holding layer 2 and the n− type drift layer 1 reaches the breakdown electric field strength. The breakdown voltage depends on the electric field distribution in the p− type breakdown voltage holding layer 2 and the n− type drift layer 1. As described above, the electric field distribution of the n− type drift layer 1 changes due to the variation of the breakdown voltage. However, the electric field distribution of the p− breakdown voltage holding layer 2 is constant, so that the electric field distribution mainly depends on the impurity concentration and thickness of the n− type drift layer 1. In other words, the magnitude of the breakdown voltage mainly depends on the n− type drift layer 1 and does not affect the p− breakdown voltage holding layer 2. Thus, the value range of the sheet carrier and impurity concentration of the p− type breakdown voltage holding layer 2 is constant without depending on the breakdown voltage.

Next, the gate drive sequence according to the present embodiment will be described.

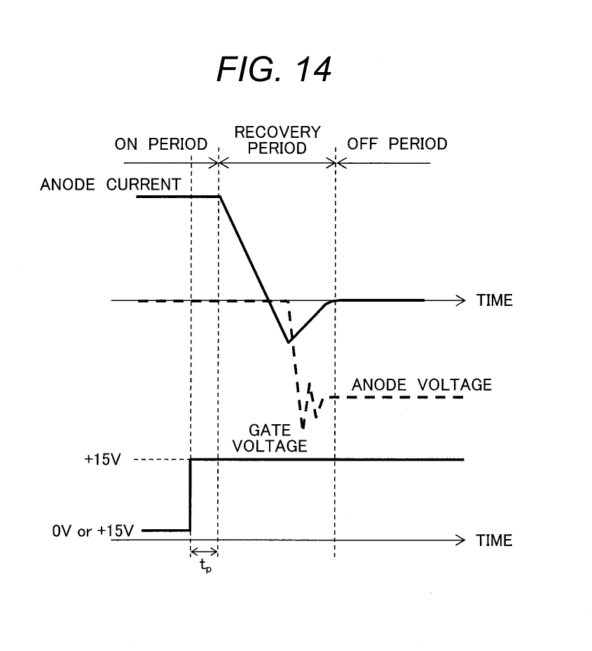

FIG. 14 shows the gate drive sequence during recovery. The upper part shows the waveforms of the anode current and the anode voltage during recovery of the diode, and the lower part shows the waveform of the gate voltage. The positive voltage is applied to the gate electrode just before the anode current is reduced. In this way, the hole density is reduced and thus the recovery loss is reduced. The gate drive sequence of FIG. 14 is different from the gate drive sequence of FIG. 7 in that the positive voltage (+15 V) continues to be applied to the gate also after the negative voltage is applied to the anode. The present embodiment has the p− type breakdown voltage holding layer 2, having a reverse breakdown voltage even in the state in which the positive voltage is applied to the gate electrode 8. For this reason, the breakdown voltage can be maintained without returning the gate voltage to 0 V. As a result, the control of the gate drive can be simplified.

Similarly to the first embodiment, also with this embodiment, it is possible to reduce power loss and noise, so that it is possible to increase the efficiency and reduce the size of the semiconductor device and the power conversion device using the same.

### Third Embodiment

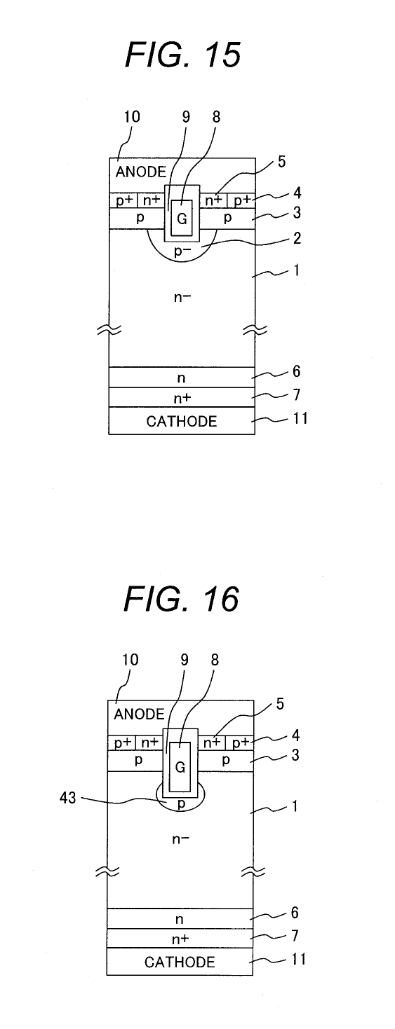

FIG. 15 is a cross sectional view of an insulated gate type vertical semiconductor device which is a third embodiment of the present invention. The present embodiment is different from the second embodiment in that the p− type breakdown voltage holding layer 2 is provided so as to cover the bottom portion of the trench gate, namely, a part of the outside of the p type channel layer 3. Thus, the p− type breakdown voltage holding layer 2 and the n− type drift layer 1 form a pn junction in this area. Further, the p type channel layer 3 and the n− type drift layer 1 form a pn junction in other areas. In other words, the p− type breakdown voltage holding layer 2 is partially provided inside the n− type drift layer 1 so as to cover the gate oxide film 9 which is located outside the surface of the p channel layer 3.

In the present embodiment, the p− type breakdown voltage holding layer 2 can prevent the depletion layer from reaching the n type inversion layer that is formed at the interface of the gate insulating film 9 upon application of the reverse voltage.

Note that also in the present embodiment, it may be possible to reduce the potential of the channel with respect the electrons by setting the gate voltage to a positive voltage lower than the threshold value, in place of forming the n type inversion layer by setting the gate voltage equal to or greater than the threshold value.

Also with this embodiment, it is possible to reduce power loss and noise, so that it is possible to increase the efficiency and reduce the size of the semiconductor device and the power conversion device using the same.

### Fourth Embodiment

FIG. 16 is a cross-sectional view of an insulated gate type vertical semiconductor device which is a fourth embodiment of the present invention. The present embodiment is different from the first embodiment in that a p type region 43 is provided in the bottom portion of the trench gate which is located outside the p type channel layer 3. A part of the n− type drift layer 1 is interposed between the p type region 43 and the p type channel layer 3, so that the p type region 43 is not brought into contact with the p type channel layer 3. In other words, the p type region 43 is provided within the n− type drift layer 1 in such a way that the p type region 43 is separated from the p type channel layer 3 and covers the gate oxide film 9 which is located outside the surface of the p type channel layer 3.

In the present embodiment, it is possible to reduce the electric field reaching the n type inversion layer formed over the surface of the p type channel 3, by the contact (pinch-off) of the depletion layers extending from a plurality of neighboring p type regions 43 not shown, or by the contact of the depletion layer extending from the p type region 43 with the depletion layer extending from the p type channel layer 3.

Note that also in the present embodiment, it may be possible to reduce the potential of the channel with respect to the electrons by setting the gate voltage to a positive voltage lower than the threshold value, in place of forming the n type inversion layer by setting the gate voltage equal to or greater than the threshold value.

Also with this embodiment, it is possible to reduce power loss and noise, so that it is possible to increase the efficiency and reduce the size of the semiconductor device and the power conversion device using the same.

### Fifth Embodiment

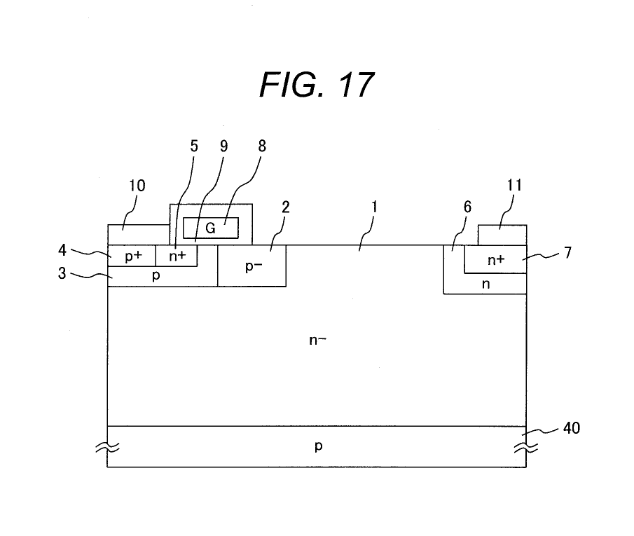

FIG. 17 is a cross-sectional view of an insulated gate type lateral semiconductor device which is a fifth embodiment of the present invention. The present embodiment is different from the second embodiment in that the insulated gate having the gate electrode 8 and the gate insulating film 9, as well as the anode electrode 10 and the cathode electrode 11 are all provided over one surface of the n− drift layer 1. Note that the production process of the lateral semiconductor device is close to the production process of IC (Integrated Circuits), so that the lateral semiconductor device is easy to be mounted to the IC.

Similarly to the first embodiment, also with this embodiment, it is possible to reduce power loss and noise, so that it is possible to increase the efficiency and reduce the size and cost of the semiconductor device and the power conversion device using the same.

### Sixth Embodiment

Next, a drive device for driving semiconductor circuits using the semiconductor devices according to the first to fifth embodiments will be described.

FIG. 19 shows a drive device of a semiconductor circuit, which is a sixth embodiment of the present invention. The present embodiment includes: a control circuit 20; two drive circuits 21 for driving an upper arm IGBT 23 and a lower arm IGBT 24 in response to an IGBT instruction signal from the control circuit 20; and two drive circuits 22 for driving an upper arm insulated gate control diode 25 and a lower arm insulated gate control diode 26 in response to a diode instruction signal from the control circuit 20. Here, any of the first to fifth embodiments described above is used as the insulated gate control diodes 25 and 26. Note that the circuit symbol of each of the insulated gate control diodes 25 and 26 in the figure shows that the resistance value of the diode is controlled by the gate electrode. However, this symbol is not commonly used and is generated by the inventors.

As described in FIG. 7, in the insulated gate control diode which is an embodiment of the present invention, the positive voltage is applied to the gate electrode just before the anode current starts to drop, namely, just before recovery, in order to reduce the recovery loss. Here, the recovery of the diode is a phenomenon associated with turn-on of the IGBT of the opposite arm to the arm of the diode. Thus, in the drive circuit according to the present embodiment, the control circuit 20 generates the IGBT instruction signal and the diode instruction signal so that the timing when the IGBT is turned on and the timing when the positive voltage is applied to the gate electrode of the insulated gate control diode of the opposite arm to the particular IGBT are synchronized with each other. In this way, it is possible to apply the positive voltage to the gate electrode just before recovery.

According to the present embodiment, similarly to the other embodiments, it is possible to increase the efficiency and reduce the size of the semiconductor device and the power conversion device using the same.

### Seventh Embodiment

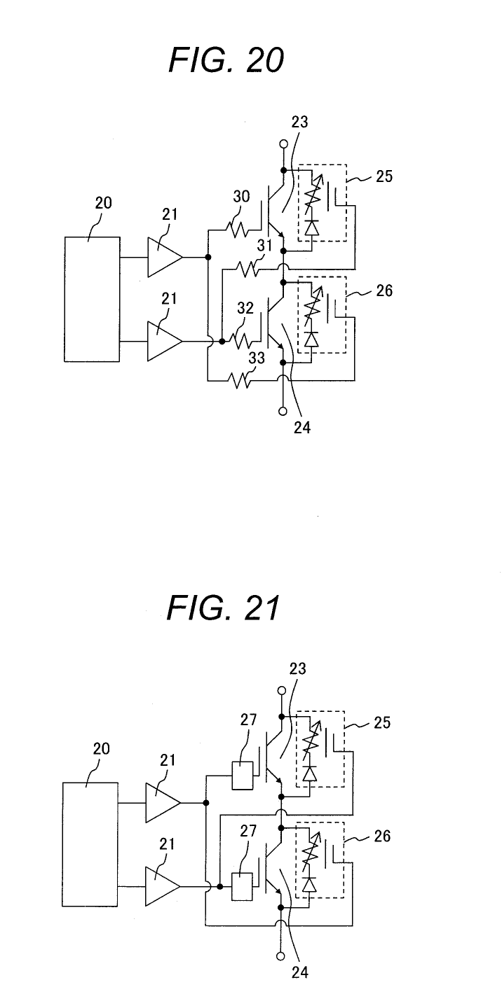

FIG. 20 shows a drive device of a semiconductor circuit, which is a seventh embodiment of the present invention. The present embodiment is different from the sixth embodiment in that the number of outputs of the control circuit 20 is reduced from 4 to 2. More specifically, one of the two outputs of the control circuit 20 is coupled to the drive circuit for driving the upper arm IGBT 23 and the lower arm insulated gate control diode 26. The other is coupled to the drive circuit for driving the upper arm insulated gate control diode 25 and the lower arm IGBT 24. A gate resistance 30 of the upper arm IGBT 23 is set greater than a gate resistance 33 of the lower arm insulated gate control diode 26, in order to turn on the IGBT 23 after the positive voltage is applied to the gate electrode of the insulated gate control diode 26. In other words, it is possible to apply the positive voltage to the gate of the insulated gate control diode just before recovery. Similarly, a gate resistance 32 of the lower arm IGBT 24 is set greater than the gate resistance 33 of the upper arm insulated gate control diode 25, in order to turn on the IGBT 24 after the positive voltage is applied to the gate electrode of the diode 25. In other words, it is possible to apply the positive voltage to the gate of the insulated gate control diode just before recovery.

According to the present embodiment, in addition to the same effects as those of the other embodiments, it is possible to reduce the size of the drive device, so that it is possible to reduce the size of the power conversion device.

### Eighth Embodiment

FIG. 21 shows a drive device of a semiconductor circuit, which is an eighth embodiment of the present invention. The present embodiment is different from the seventh embodiment in that delay circuits 27 are provided in the drive circuit of the upper arm IGBT 23 and in the drive circuit of the lower arm IGBT 24, respectively, in place of the gate resistances 31 to 34 in FIG. 20. In other words, the delay circuits 27 are coupled between the drive circuit for driving the upper arm IGBT 23 and the lower arm insulated gate control 26, and the gate of the upper arm IGBT 23, and between the drive circuit for driving the lower arm IGBT 24 and the upper arm insulated gate control 25, and the gate of the lower arm IGBT 24. In this way, similarly to the seventh embodiment, it is possible to turn on the IGBT after the positive voltage is applied to the gate of the insulated gate control diode. In other words, it is possible to apply the positive voltage to the gate of the insulated gate control diode just before recovery.

According to the present embodiment, in addition to the same effects as those of the other embodiments, it is possible to reduce the size of the drive circuit, so that it is possible to reduce the size of the power conversion device.

### Ninth Embodiment

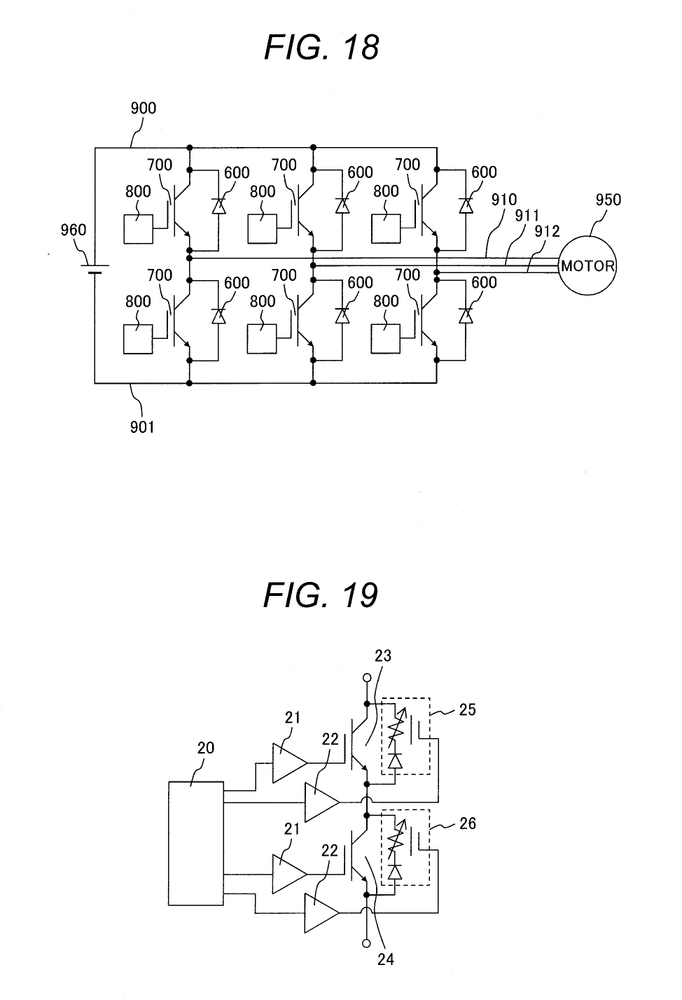

A power conversion device which is a ninth embodiment of the present invention will be described with reference to FIG. 18.

The present embodiment is a three-phase inverter device, in which the insulated gate control diodes and drive circuits described in the above embodiments are respectively used as the diode 600 and the gate drive circuit. Note that the circuit symbol of a common diode is used for the insulated gate control diode in FIG. 18 for convenience. Further, the gate drive circuit 800 is shown by a simple block diagram and the detailed circuit configuration as shown in FIGS. 19 to 21 is not shown here.

The present embodiment includes a pair of DC terminals 900 and 901, and AC terminals for the same number of AC phases, namely, three AC terminals 910, 911, and 912. An IGBT 700 is coupled between each of the DC terminals and each of the AC terminals, which is used as one semiconductor switching element. Thus, the three-phase inverter device as a whole includes six IGBTs. Further, the diode 600 is connected in reverse parallel to each IGBT. Note that the number of IGBTs 700 and diodes 600 is set to an appropriate number according to the number of AC phases, the power capacity of the power conversion device, as well as the breakdown voltage and current capacity of a single unit of the semiconductor switching element 700.

Each IGBT 700 and each diode 600 are driven by the gate drive circuit 800. In this way, the DC power received by the DC terminals 900 and 901 from the DC power supply 960 is converted to AC power. Then, the AC power is output from the AC terminals 910, 911, and 912. Each AC output terminal is coupled to the motor 950 such as an induction machine or a synchronous machine. In this way, the motor 950 is rotated and driven by the AC power output from each of the AC terminals.

According to the present embodiment, the insulated gate control diodes of the first to fifth embodiments are used as the diode 600, and the drive circuits of the sixth to eighth embodiments are also used. In this way, it is possible to reduce the power loss of the diode, and to reduce the loss and size of the inverter device.

Although the present embodiment is an inverter device, the semiconductor devices and the drive circuits according to the present invention can also be applied to other power conversion devices such as a converter and a chopper, with which the same effect can be obtained.

It should be understood that the present invention is not limited to the above embodiments and various changes and modifications can be made within the scope of the technical idea of the present invention. For example, in the above embodiments, the conductivity type of each semiconductor layer may be reversed. Further, the semiconductor material configuring the semiconductor device is not limited to silicon as used in the above embodiments, and may be wide-gap materials such as SiC (silicon carbide) and GaN (gallium nitride).

### REFERENCE SIGNS LIST

1: n− type drift layer

2: p− type breakdown voltage holding layer

3: p type channel layer

4: p+ type anode layer

5: n+ type anode layer

6: n type buffer layer

7: n+ type cathode layer

8: gate electrode

9: gate insulating film

10: anode electrode

11: cathode electrode

20: control circuit

21: drive circuit of IGBT

22: drive circuit of diode

23: upper arm IGBT

24: lower arm IGBT

25: upper arm diode

26: lower arm diode

27: delay circuit

30, 31, 32, 33: gate resistance

40: p type substrate

43: p type region

600: flywheel diode

700: IGBT

800: gate circuit

900, 9010: DC terminal

910, 911, 912: AC terminal

950: motor

960: DC power supply

1. A semiconductor device comprising:
a first semiconductor layer of a first conductivity type;
a second semiconductor layer of the first conductivity type, which is adjacent to the first semiconductor layer and has an impurity concentration lower than the first semiconductor layer;
a third semiconductor layer of a second conductivity type adjacent to the second semiconductor layer;
a fourth semiconductor layer of the first conductivity type located within the third semiconductor layer;
a first electrode electrically coupled to the third semiconductor layer and the fourth semiconductor layer;
a second electrode electrically coupled to the first semiconductor layer; and
an insulated gate provided over each of the surfaces of the third semiconductor layer and the fourth semiconductor layer,
wherein the peak value of the impurity concentration of the third semiconductor layer is in the range of 2×10¹⁶ cm⁻³ or more and 5×10¹⁸ cm⁻³ or less.

2. A semiconductor device according to claim 1,
wherein the semiconductor device comprises a fifth semiconductor layer of the second conductivity type located between the second semiconductor layer and the third semiconductor layer, having an impurity concentration lower than the third semiconductor layer.

3. A semiconductor device according to claim 2,
wherein the fifth semiconductor layer is partially provided inside the second semiconductor layer so as to cover a gate oxide film of the insulated gate which is located outside the surface of the third semiconductor layer.

4. A semiconductor device according to claim 2,
wherein the sheet carrier of the fifth semiconductor layer is in the range of 1.5×10¹⁰ cm⁻² or more and 1×10¹² cm⁻² or less.

5. A semiconductor device according to claim 2,
wherein the impurity concentration of the fifth semiconductor layer is in the range of 1.5×10¹⁵ cm⁻³ or more and 1×10¹⁷ cm⁻³ or less.

6. A semiconductor device according to claim 1,
wherein a sixth semiconductor layer of second conductivity type, which is separated from the third semiconductor layer and covers the gate oxide film of the insulated gate located outside the surface of the third semiconductor layer, is partially provided inside the second semiconductor layer.

7. A semiconductor device according to claim 1,
wherein the first electrode, the second electrode, and the insulated gate are located over the same surface in the second semiconductor layer.

8. A semiconductor device according to claim 1,
wherein a positive voltage is applied to the insulated gate before the semiconductor device moves from a conductive state to a non-conductive state.

9. A semiconductor device according to claim 8,
wherein 0 volt or a negative voltage is applied to the insulated gate before the potential of the second electrode is at a higher level than the first electrode.

10. A semiconductor device according to claim 8,
wherein the difference between the time point when the current of the semiconductor device is reduced and the time point when the positive voltage is applied to the insulated gate, is 2 μs or more.

11. A drive device of a semiconductor circuit having an upper arm and a lower arm, each including a parallel circuit of a semiconductor switching element and a diode, in which a semiconductor device according to claim 1 is used as the diode,
wherein the drive device includes:
a plurality of drive circuits coupled to each of the semiconductor switching elements and each of the diodes; and
a control circuit for generating an instruction signal given to the drive circuits.

12. A drive device of a semiconductor circuit having an upper arm and a lower arm, each including a parallel circuit of a semiconductor switching device and a diode, in which a semiconductor device according to claim 1 is used as the diode,
wherein the drive device includes:
a first drive circuit for driving the semiconductor switching element of the upper arm as well as the diode of the lower arm;
a second drive circuit for driving the semiconductor switching element of the lower arm as well as the diode of the upper arm; and
a control circuit for generating an instruction signal given to the first and second drive circuits,
wherein the resistance value of a first gate resistance, which is coupled between the gate of the semiconductor switching element of the upper arm and the first drive circuit, is greater than the resistance value of a second gate resistance coupled between the gate of the diode of the lower arm and the first drive circuit,
wherein the resistance value of a third gate resistance, which is coupled between the gate of the semiconductor switching element of the lower arm and the second drive circuit, is greater than the resistance value of a fourth gate resistance coupled between the gate of the diode of the upper arm and the second drive circuit.

13. A drive device of a semiconductor circuit having an upper arm and a lower arm, each including a parallel circuit of a semiconductor switching element and a diode, in which a semiconductor device according to claim 1 is used as the diode,
wherein the drive device includes:
a first drive circuit for driving the semiconductor switching element of the upper arm as well as the diode of the lower arm;
a second drive circuit for driving the semiconductor switching element of the lower arm as well as the diode of the upper arm; and
a control circuit for generating an instruction signal given to the first and second drive circuits,
wherein the semiconductor circuit includes:
a first delay circuit coupled between the gate of the semiconductor switching element of the upper arm, and the first drive circuit; and
a second delay circuit coupled between the gate of the semiconductor switching element of the lower arm, and the second drive circuit.

14. A power conversion device comprising:
a pair of DC terminals;
the same number of AC terminals as the number of AC phases;
a plurality of semiconductor switching elements connected between the DC terminals and the AC terminals; and
a plurality of diodes connected in reverse parallel to the semiconductor switching elements,
wherein the diode is a semiconductor device according to claim 1.
